(19) United States
(12) Patent Application Publication
(10) Pub. No.: US 2024/0243546 A1
(43) Pub. Date: Jul. 18, 2024

(54) VCSEL MODULE

(71) Applicants: Citizen Electronics Co., Ltd., Fujiyoshida-shi, Yamanashi (JP); Citizen Watch Co., Ltd., Nishitokyo-shi, Tokyo (JP)

(72) Inventors: Takashi AKIYAMA, Fujiyoshida-shi, Yamanashi (JP); Jin UCHIMURA, Fujiyoshida-shi, Yamanashi (JP); Kenshi AIHARA, Fujiyoshida-shi, Yamanashi (JP); Hiroaki HARA, Fujiyoshida-shi, Yamanashi (JP)

(21) Appl. No.: 18/012,628

(22) PCT Filed: Jun. 22, 2021
(86) PCT No.: PCT/JP2021/023664

§ 371 Date: Dec. 22, 2022

(30) Foreign Application Priority Data
Jun. 22, 2020 (JP) 2020-107020
Mar. 25, 2021 (JP) 2021-052423

(51) Int. Cl. H01S 5/042; H01S 5/02345; H01S 5/0239; H01S 5/024; H01S 5/183

(52) U.S. Cl. CPC H01S 5/0428; H01S 5/02345; H01S 5/0239; H01S 5/02469; H01S 5/04256; H01S 5/183

(57) ABSTRACT

A VCSEL module includes a VCSEL, a switching element disposed below the VCSEL and electrically connected to the VCSEL, and a substrate disposed below the switching element, and electrically connected to the switching element.

### FIELD

The present invention relates to a VCSEL (Vertical Cavity Surface Emitting Laser) module using a VCSEL as a light source.

### BACKGROUND

A range finding device is described in JP 2016-45066 that measures a distance based on light (hereinafter referred to as reflected light) which is obtained by emitting pulsed light from a light source and reflecting the pulsed light by an object. The above range finding device includes a range image sensor, a light source and a control unit. The range image sensor is a charge-distributing type range image sensor, and the light source of the range image sensor is a laser beam irradiation device such as a VCSEL module, a LED and etc. The control unit has the light source output a pulsed light (light intensity signal SLP), by applying a drive signal SD to the light source, and outputs a first transfer signal S1 and a second transfer signal S2 to the range image sensor.

FIG. 24 is a timing chart for explaining a method for measuring a distance in the above range finding device. In the above range finding device, the effect of the rising time TP and falling time TF of the light intensity signal SLP to the range finding accuracy is reduced, and therefore the range finding accuracy is improved.

A laser diode module 600 having improved rising characteristics of a light source is describes in U.S. Patent Application Publication No. 2018/0278011. FIG. 25 is a perspective view of the laser diode module 600. The laser diode module 600 includes a substrate 610, a laser diode 620 including a plurality of laser diodes DL, a capacitor 630 including a capacitors C1 and C2, and an IC4 including a driver circuit 640 including a transistor TL connected in series with the laser diode DL. The laser diode 620 emits light in the direction of an arrow G.

FIG. 26 is a circuit diagram of the laser diode module 600 shown in FIG. 25. The laser diode module 600 includes a power supply terminal Vs, a control terminal ON and a ground terminal GND. The transistor TL for switching and the laser diode DL are connected in series between the power supply terminal Vs and the ground terminal GND, and the capacitors C1 and C2 are connected in parallel to the series circuit. The control terminal ON is connected to a gate electrode of the transistor TL.

A light emitting device is described in JP 2009-105240 that includes a VCSEL and a resistor connected in series with the VCSEL and having a positive temperature properties. The above light emitting device may prevent a high-frequency noise from generating, and prevent a drive signal from degrading, by impedance mismatch, by compensating for the temperature change of the impedance characteristics of the VCSEL by the resistor connected in series to the VCSEL.

A miniaturized optical interconnection device is described in JP 2004-31456 in which an IC drivers is disposed on a upper surface of a sub-mount substrate, a VCSEL is disposed on a lower surface thereof, and the sub-mount substrate is disposed on an upper portion of a substrate.

A device is described in FIG. 16 of U.S. Pat. No. 8,488,921 in which a sub-mount is disposed on an upper portion of a printed wiring substrate, an IC chip is disposed on an upper portion of the sub-mount, and a VCSEL is disposed on an upper portion of the IC chip.

An optical module is described in FIG. 2 of JP 2009-8721 in which an emitting element array is disposed on an upper portion of a printed circuit substrate, a drive IC is disposed on an upper portion of the light emitting element array, and a memory IC is disposed on an upper portion of the drive IC.

### SUMMARY

However, no VCSEL modules having a three stage stacked structure are described in any documents in which a switching element is disposed on an upper portion of a substrate, and a VCSEL is disposed on an upper portion of the switching element.

An object of the present invention is to provide a miniaturized VCSEL module in which a VCSEL and switching element is integrated.

A VCSEL module according to an embodiment includes a VCSEL, a switching element disposed below the VCSEL and electrically connected to the VCSEL, and a substrate disposed below the switching element, and electrically connected to the switching element.

It is preferable for the above VCSEL module to further includes a current control element disposed between VCSEL and the switching element or between the switching element and the substrate, and the current control element is electrically connected in series with VCSEL and the switching elements.

It is preferable for the above VCSEL module to further includes a wiring electrode formed on the substrate, and the switching element or the current control element is electrically connected to the wiring electrode via a solder ball, a stud bump or a metal piece.

In the above VCSEL module, it is preferable that the connecting portion of the wiring electrode to be connected to the gate electrode of the current control element is formed thicker than the other portions.

It is preferable for the above VCSEL module to further includes a capacitor electrically connected to the VCSEL.

It is preferable for the above VCSEL module to further includes a first electrode made of metal, the substrate functions as a second electrode made of metal, the VCSEL includes a VCSEL first terminal disposed on an upper surface, and a VCSEL second terminal disposed on a lower surface, the switching element is formed in a semiconductor device, the semiconductor device includes a first terminal connected to the first electrode and the VCSEL first terminal, a second terminal connected to the VCSEL second terminal, and a third terminal connected to the second electrode.

In the above VCSEL module, it is preferable that the semiconductor device includes a current control element for controlling a current flowing through the VCSEL, and the current control element is connected between the second terminal and the switching element or between the switching element and the third terminal.

In the above VCSEL module, it is preferable that the semiconductor device has a rectangular planar shape including a first side, a second side and a third side perpendicular to the first side, a fourth side facing the first side, an upper surface and a lower surface, the first terminal is disposed at an end of the upper surface along the first side close to the first electrode, the second terminal is disposed in the central portion of the upper surface, and the third terminal is disposed at an end of the upper surface along the second or third side.

In the above VCSEL module, it is preferable that the first electrode and the first terminal are connected by a plurality of bonding wires.

In the above VCSEL module, it is preferable that the second electrode and the third terminal are connected by a plurality of bonding wires.

In the above-described VCSEL module, it is preferable that the semiconductor device incudes a monitor circuit relating to a temperature of the VCSEL, a current flowing through the VCSEL or an amount of light emitted from the VCSEL, and a monitor circuit terminal connected to the monitor circuit is disposed at an end along the fourth surface of the upper surface of the semiconductor device.

It is preferable for the above VCSEL module to further include a third electrode connected to the monitor circuit terminal.

It is preferable for the above VCSEL module to further include a resin frame formed so as to cover portions of the surfaces of the first electrode and the second electrode, and portions of the surfaces of the first terminal and the third terminal.

In the above-described VCSEL module, it is preferable that the frame includes a support surface, and an opening through which the VCSEL is visually recognized is formed on the support surface.

It is preferable for the above VCSEL module to further include an optical element supported by the support surface and transmitting light emitted from the VCSEL.

In the above light emitting device, it is preferable that the frame includes a convex portion disposed over the support surface and protruding inwardly from an outer wall of the frame, in order to position the optical element.

In the above VCSEL module, it is preferable that in the semiconductor device, a heat dissipation path for transferring heat radiation from the VCSEL to the second electrode is formed between the second terminal and the lower surface of the semiconductor device.

In the above VCSEL module, it is preferable that the semiconductor device incudes a fourth terminal connected to the second electrode, the fourth terminal is disposed at the end of the upper surface along the other of the second or third side where the third terminal is disposed, and a current flowing into the semiconductor device from the VCSEL second terminal of the VCSEL flows to the second electrode, and is divided into left and right sides of the semiconductor device via the third terminal and the fourth terminal.

A VCSEL module according to an embodiment, a miniaturized VCSEL module in which a VCSEL and a switching element is integrated may be provided.

### BRIEF DESCRIPTION OF THE DRAWINGS

FIG. 1 is a side view of a VCSEL module 100 according to a first embodiment;

FIG. 2A is a bottom view of a first FET 201 included in VCSEL module 100;

FIG. 2B is a top view thereof of the first FET 201;

FIG. 3 is a circuit diagram of the VCSEL module 100 shown in FIG. 1;

FIG. 4 is a characteristic diagram of the VCSEL module 100 shown in FIG. 1;

FIG. 5A to 5F are diagrams for explaining a manufacturing process for the VCSEL module 100;

FIG. 6A to 6F are diagrams explaining for a manufacturing process for a VCSEL module 130 according to a first modification of VCSEL module 100;

FIG. 7A to 7F are diagrams explaining for a manufacturing process for a VCSEL module 130 according to a second modification of VCSEL module 100;

FIG. 8A shows a top view of the VCSEL module 100 with a first frame;

FIG. 8B is a sectional view along A-A of FIG. 8A;

FIG. 9A is a diagram illustrating a VCSEL module 100′ with a second frame;

FIG. 9B is a sectional view along B-B of FIG. 9A;

FIG. 10 is a perspective view of a VCSEL module 150 according to the second embodiment;

FIG. 11 is a perspective view of the VCSEL module 150 shown in FIG. 10 excluding the optical elements;

FIG. 12 is a perspective view of the VCSEL module 150 shown in FIG. 10 excluding the optical elements and the frame;

FIG. 13 is a cross sectional view of the VCSEL module 150 along C-C shown in FIG. 10;

FIG. 14 is a perspective view of the frame shown in FIG. 10;

FIG. 15 is a circuit diagram of the VCSEL module 150 shown in FIG. 10;

FIG. 16 is a diagram illustrating a connecting relationship among the second electrode, the semiconductor device and the VCSEL shown in FIG. 10;

FIG. 17 is a flow chart illustrating manufacturing methods for the VCSEL module 150 shown in FIG. 10;

FIG. 18 is a planar view corresponding to an electrode preparation step shown in FIG. 17;

FIG. 19 is a plan view corresponding to a semiconductor device mounting step shown in FIG. 17;

FIG. 20 is a plan view corresponding to a light emitting element mounting step shown in FIG. 17;

FIG. 21 is a planar view corresponding to a wire bonding step shown in FIG. 17;

FIG. 22 is a plan view corresponding to a frame forming step shown in FIG. 17;

FIG. 23A is a plan view of a base of the frame 318 of the VCSEL module 150 shown in FIG. 10;

FIG. 23B is a cross-sectional view of the VCSEL module 150 along D-D of FIG. 23A;

FIG. 23C is a cross-sectional view of the VCSEL module 150 along E-E of FIG. 23A;

FIG. 24 is a timing chart for explaining of a range finding device as a conventional art;

FIG. 25 is a perspective view of the laser diode module 600 as a conventional art; and

FIG. 26 is a circuit diagram of the laser diode module 600 shown in FIG. 25.

### DESCRIPTION OF EMBODIMENTS

Hereinafter, preferred embodiments of VCSEL modules will be described with reference to figures. However, the technical scope of the present invention is not limited to those embodiments, and extends to the invention described in the claims and equivalents thereof. In the explanations for the drawings, the same or equivalent elements are denoted by the same reference numerals, and redundant descriptions are omitted. The scale of members may be changed as appropriate for explanation.

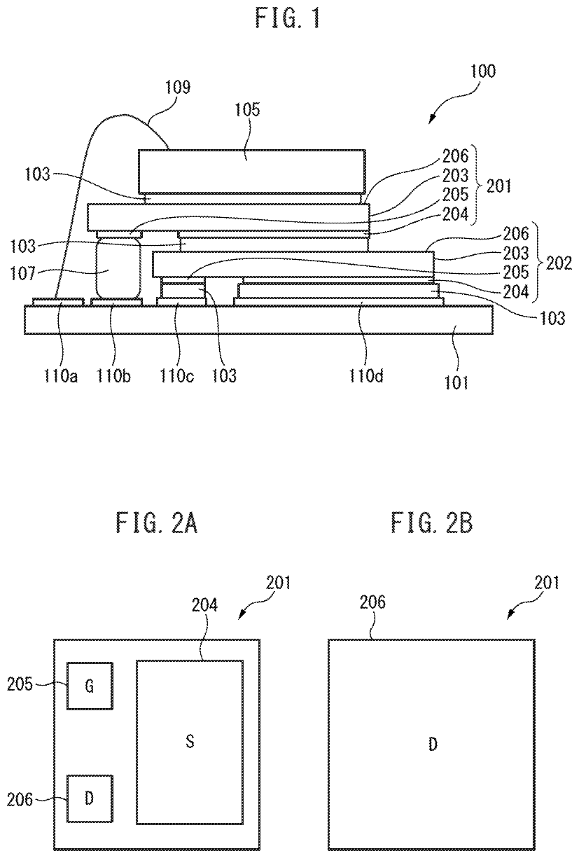

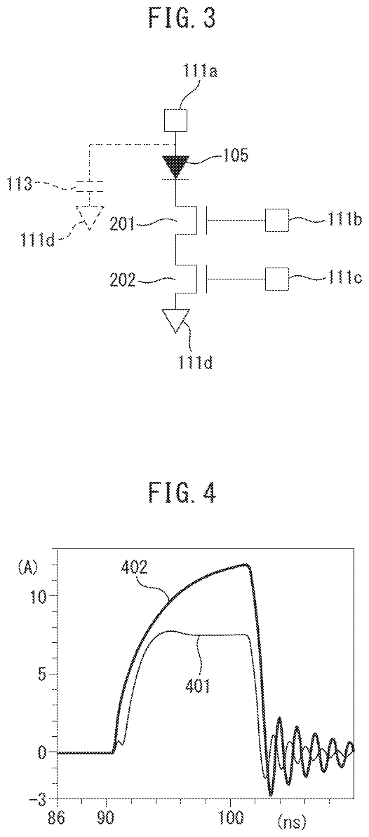

FIG. 1 is a side view of a VCSEL module 100 according to a first embodiment. As shown in FIG. 1, the VCSEL module 100 includes a substrate 101, a VCSEL 105, a first FET 201 and a second FET 202. The second FET 202, the first FET 201 and VCSEL 105 are stacked in the order on the substrate 101 from the lower side of the figure. Although a capacitor 113 (refer to FIG. 3) is mounted on the substrate 101, and terminal electrodes for connecting to an external circuit is formed thereon, members constituting the stack structure, i.e., the VCSEL 105, the first FET 201, the second FET 202 and the member using for mounting these elements are only illustrated. Although an optical element for controlling the light distribution of the VCSEL 105 such as a lens may be disposed on the VCSEL 105, and a wall structure may be disposed around the stacked structure, these elements will be explained later.

The substrate 101 is a flat plate, the base material of the substrate 101 is made of aluminum nitride, and a patterned metal layers (wiring electrodes 110a to 110d and etc., are disposed on the upper surface of the substrate 101. The base material is not limited to aluminum nitride, and may be a resin such as an FR4.

The VCSEL 105 is a surface emitting type light source, and is an aggregate of laser diodes whose anodes are disposed on an upper surface and whose cathodes are disposed on a lower surface. The anodes are connected to the wiring electrode 110a by a bonding wire 109, and the cathodes are connected to a drain electrode 206 of the first FET 201 via a first conductive connecting member 103. The thickness of the VCSEL 105 is 200 microns and the plane size thereof is 1.0 mm×1.0 mm, however the size is not limited thereto.

In the first FET 201, a drain electrode 206 is disposed over the entire upper surface of FET die 203, and a source electrode 204 and a gate electrode 205 are disposed on a lower surface thereof. The source electrode 204 included in the first FET 201 is connected to a drain electrode 206 included in the second FET 202 via the first conductive connecting member 103, a gate electrode 205 included therein is connected to a wiring electrode 110b via a second conductive member 107. The second FET 202 has the same structure as that of the first FET 201, a source electrode 204 and a gate electrode 205 included in the second FET 202 is connected to a wiring electrode 110d and a wiring electrode 110c via the first conductive connecting members 103, respectively. The thicknesses of the first and second FETs 201 and 202 are 100 microns, the plane size thereof is 1.4 mm×1.4 mm, and electrodes 204 to 206 are Ni—Au plated. The first conductive connecting members 103 are members having adhesiveness and conductivity such as sintered Ag, AuSn and solder, as long as the first conductive connecting members 103 have adhesiveness and conductivity, are not limited thereto.

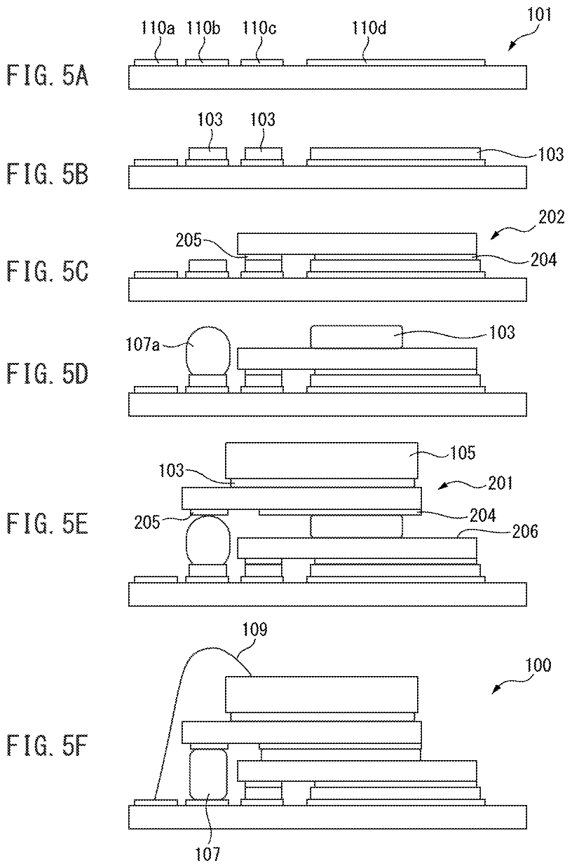

The second conductive member 107 includes a solder ball 107a (refer to FIG. 5), as a member having height. In addition thereto, a solder plate, gold bump or a metal plate may be used as the second conductive member 107. It is preferable that the first conductive connecting members 103 and the second conductive member 107 are formed by a metal material having a low electrical resistivity. When the first conductive connecting members 103 and the second conductive member 107 are formed by such a metal, impedance of the VCSEL module 100 may be low, and therefore it is easy for the VCSEL module 100 to flow a large current in a short period of time.

FIG. 2A is a bottom view of the first FET 201 included in VCSEL module 100, and FIG. 2B is a top view thereof. As shown in FIG. 2A, a drain electrode 206 having a small area and shown as “D”, a source electrode 204 having a large area and shown as “S”, and a gate electrode 205 having the small area shown as “G” are disposed on the lower surface of the first FET 201. As shown in FIG. 2 B, a drain electrode 206 disposed on all of the upper surface and shown as “D” is disposed on the upper surface of the first FET 201.

The drain electrode 206 on the lower surface is connected to the drain electrode 206 on the upper surface in the first FET 201, and is not connected to the wiring electrodes 110a to 110d on the substrate 101 (see FIG. 1). Since the first FET 201 has a trench construction, a current flows from the upper surface of the first FET 201 to the lower surface thereof. Since the structure and properties of the second FET 202 are exactly the same as those of the first FET 201, detailed explanations of the second FET 202 will be omitted.

FIG. 3 is a circuit diagram of the VCSEL module 100. Although the VCSEL 105, first and second FETs 201 and 202 are shown as circuit elements in FIG. 1, a capacitor 113 is further mounted on the substrate 101, as above explained. The capacitor 113 and circuits relating to the capacitor 113 are shown by a dotted line in FIG. 3.

As shown in FIG. 3, the VCSEL module 100 further includes a power supply terminal 111a, a gate terminal 111b of the first FET 201, a gate terminal 111c of the second FET 202 and a source terminal 111d. As shown in FIG. 3, the VCSEL 105, the first FET 201 and the second FET 202 are connected in series between the power supply terminal 111a and the source terminal 111d, and the capacitor 113 is connected in parallel to the series circuit. Each of terminals 111a to 111d is a terminal electrode formed on the lower surface of the substrate 101 for connecting to an external device, and is electrically connected to wiring electrodes 110a to 110d via a through hole or via disposed in the substrate 101.

An external power supply (not shown) charges the capacitor 113 via the power supply terminal 111a, mainly when the VCSEL 105 does not emit light. On the other hand, although it is necessary for the VCSEL module 100 to flow a large current in a short period only about 10 (ns), when the VCSEL 105 emits light, it is not easy for an external power supply to respond in the short period, and therefore a required current is not supplied via the power supply terminal 111a in only in the short period. Thus, a current for emitting the VCSEL 105 is mostly obtained by discharging the capacitor 113.

A predetermined constant voltage is applied to the gate terminal 111b from an external, and the first FET 201 functions as a current control element. Control pulses having a width of about 10 (ns) are applied to the gate terminal 111c from an external, and the second FET 202 functions as a switching device.

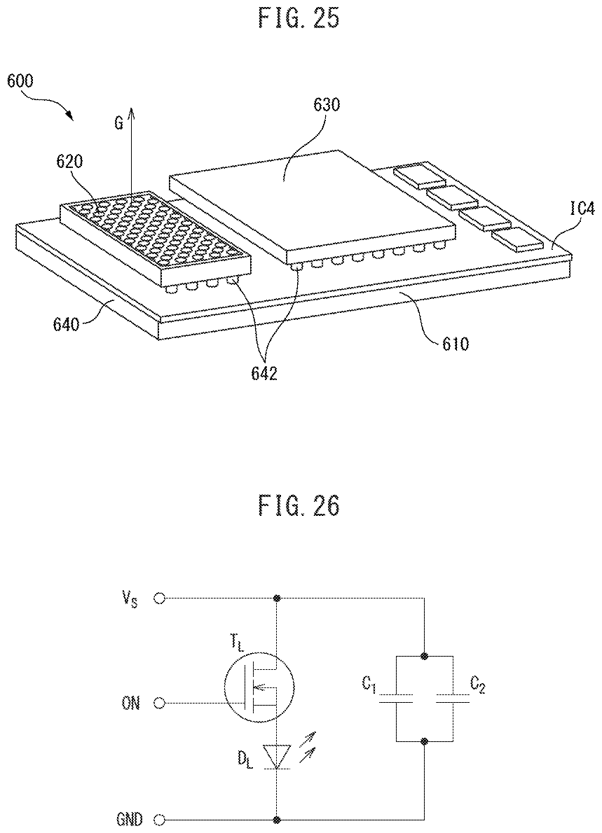

FIG. 4 is a characteristic diagram of a current 401 flowing through the VCSEL 105 obtained by a simulating, when a control pulse having a width of 10 (ns) is applied to the gate terminal 111c (refer to FIG. 3). The vertical axis represents a current (A), and the horizontal axis represents time (ns). In FIG. 4, a current 402 flowing through the laser diode DL of the laser diode module 600 shown in FIGS. 25 and 26 as conventional examples is also shown for a comparison.

In the simulating, an inductance of a current path returning to the capacitor 113 through the VCSEL 105 from the capacitor 113 is set to 1 (nH). As shown in FIG. 4, the VCSEL 105 enters constant current operation within 1 (ns) after a current rises, by applying a control pulse to the gated terminal 111c. On the other hand, the current value of the current 402 of the conventional example continues to rise during a period when the control pulse is applied by applying a control pulse to the gated terminal 111c. Thus, in the VCSEL module 100, the rising time in the waveform of the current 401 of

VCSEL 105 is within 1 (ns) or less with respect to the control pulse, and the waveform thereof includes a flat portion of about 8 (ns). Since the amount of light emitted from the VCSEL 105 is proportional to the amount of a current inputted to the VCSEL 105, the amount of light emitted from the VCSEL 105 may be constant during a period corresponding to the flat portion.

FIG. 5 is a diagram for explaining a manufacturing process for the VCSEL module 100. FIGS. 5A to 5F show side views of the characteristic states in each step. In FIGS. 5A to 5F, similar to FIG. 1, members other than the VCSEL 105, the first and second FETs 201 and 202 and members relating thereto are omitted.

First, as shown in FIG. 5A, the substrate 101 having an upper surface on which wiring electrodes 110a to 110d and etc., are disposed is prepared. Next, as shown in FIG. 5B, the first conductive connecting members 103 are applied on the upper surface of the wiring electrodes 110b to 110d except for the wiring electrode 110a for bonding wires. Next, as shown in FIG. 5C, the second FET 202 is connected to the substrate 101. At the time, the second FET 202 is disposed so that the gate electrode 205 and the source electrode 204 respectively overlap the wiring electrodes 110c and 110d via the first conductive connecting members 103.

Next, as shown in FIG. 5D, the solder ball 107a is disposed on the wire electrode 110b, and a first conductive connecting member 103 is applied on the upper surface of the second FET 202. Although the first conductive connecting member 103 is disposed for fixing the solder ball 107a between the solder ball 107a and the wire electrode 110b, if the solder ball 107a may be fixed by other ways such as a flux, the first conductive connecting member 103 is not necessarily required.

Next, as shown in FIG. 5E, the first FET 201 is connected to the upper surface of the second FET 202. The VCSEL 105 is connected to the upper surface of the first FET 201 in advance by the first conductive connecting member 103. Further, the gate electrode 205 included in the first FET 201 is connected to the solder ball 107a, and the source electrode 204 included therein is connected to the drain electrode 206 of the second FET 202 via the first conductive connecting member 103.

Finally, as shown in FIG. 5F, the VCSEL module 100 is heated to stabilize the connected states. At the time, the first conductive connecting members 103 are cured by first heating. Then, the solder ball 107a is connected to the first conductive connecting member 103, by increasing a temperature to melt the solder ball 107a. At the time, the solder ball 107a is connected to the gate electrode 205 of the second FET 202. The second conductive member 107 is formed by connecting the solder ball 107a and the first conductive connecting member 103. Thereafter, the bonding wires 109 connects between the anode of VCSEL 105 and the wire electrode 110a. If the first conductive connecting members 103 are not used in the second conductive member 107, the solder ball 107 is directly connected to the electrode 110b.

The VCSEL module 100 has a four stages stacked structure including the VCSEL 105, the first FET 201 that is a current control element, the second FET 202 that is a switching element, and the substrate 101, as above explained. Further, since the first FET 201 is not necessarily required, the VCSEL module 100 may have a structure (three stage stacked structure) such as stacked in three stages including the VCSEL 105, the second FET 202 serving as a switching element, and the substrate 101.

In the VCSEL 105, a substantially linearly current flows from the anode on the upper surface to the cathode on the lower surface. Similarly, in the first FET 201 and the second FET 202, a substantially linearly current flows from the drain electrode 206 on the upper surface to the source electrode 204 on the lower surface. In the stacked structure including the VCSEL 105 and the first and second FETs 201 and 202, a linearly current flows from the upper portion to the lower portion in a short distance. In the VCSEL module 100 having stacked structure, since the inductance is minimized, and rising and falling characteristics for a current are improved. Further, in the stacked structure, since a first FET 201 functioning as a current control element is disposed in the current path, even if a pulsed current having an extremely short width is applied, a current continues to rise during a period when the pulsed current is applied (see current 401 in FIG. 4).

As above explained, in the VCSEL module 100, the rise and fall times of the pulse current flowing through VCSEL 105 are 1 (ns) or less, by minimizing the inductance of the current path including the VCSEL 105, and even if the control pulse has an extremely short width, the top portion of the current waveform is flat during a period corresponding to the control pulse width, by the first FET 201 functioning as a current control element. Thus, in the VCSEL module 100, the waveform of the pulsed current flowing through the VCSEL 105 is improved so as to shape the waveform to a nearly square wave (see current 401 in FIG. 4).

In the VCSEL module 100, although the first FET 201 functions as a current control element, and the second FET 202 functions as a switching element, the arrangement of the first FET 201 and the second FET 202 may be reversed vertically.

Although the first FET 201 is disposed on the upper portion of the second FET 202, after the VCSEL 105 is mounted on the first FET 201 in advance, as explained with reference with FIG. 5E, the VCSEL 105 may be mounted on the first FET 201, after the first FET 201 is disposed on the upper portion of the second FET 202.

Although similar elements are utilized for the first FET 201 and the second FET 202 in the VCSEL module 100, FETs having different sizes may be utilized therefor, in order to achieve a stacked structure, and the effect similar to the VCSEL module 100 may be obtained in the structure.

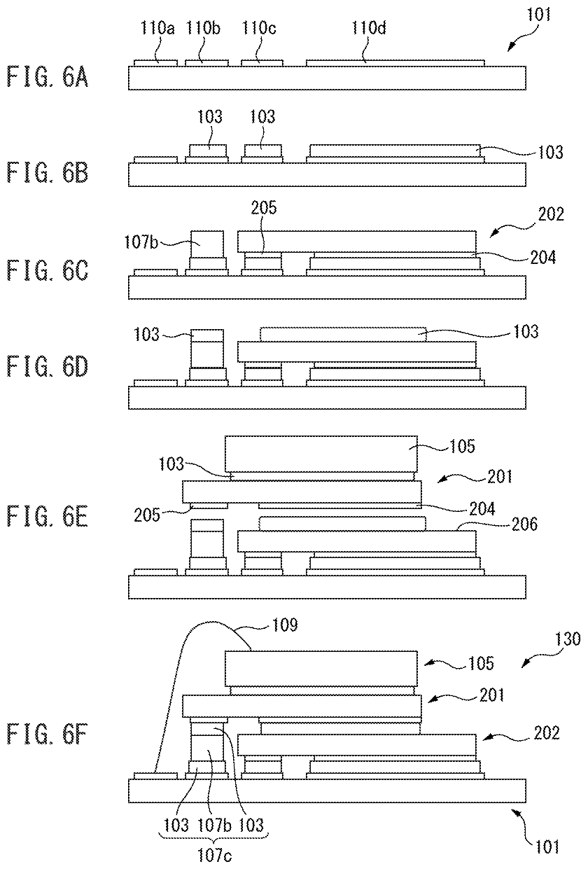

FIG. 6 is a diagram explaining for a VCSEL module 130 according to a first modification of the VCSEL module 100 and a manufacturing method thereof. Side views of a characteristic states in each step are shown in FIGS. 6A to 6F. Members such as a capacitor 113 (refer to FIG. 3), except for the VCSEL 105, the first and second FETs 201 and 202 and members relating to the VCSEL 105 are not illustrated in FIG. 6A to 6F.

An optical element and a frame that may be added are not shown therein.

The second conductive member 107 for connecting the gate electrode 205 of the first FET 201 and the wiring electrode 110b of the substrate 101 is not limited to the above-explained member including a solder ball 107a. The VCSEL module 130 including a metal piece in the second conductive member 107 will be explained.

First, the structure of the VCSEL module 130 will be explained with reference to FIG. 6F. As shown in FIG. 6F, in the VCSEL module 130, the second FET 202, the first FET 201 and the VCSEL 105 is stacked on the substrate 101 in the order from the lower side of the diagram. In a second conductive member 107c, the first conductive connecting member 103, a metal piece 107b and the first conductive connecting member 103 are stacked from below. Comparing FIG. 6F with FIG. 1, the basic structure of the VCSEL module 130 is common to that of the VCSEL module 100, only the second conductive member 107c connecting the gate electrode 205 and the wiring electrode 110b of the first FET 201 are different from the structure of the VCSEL module 100. Similarly to the VCSEL module 100, the first FET 201 is not necessarily required for the VCSEL module 130.

First, as shown in FIG. 6A, the substrate 101 having a wiring electrodes 110a to 110d on the upper surface is prepared. Next, as shown in FIG. 6B, the first conductive connecting members 103 are applied on the upper surface of the wiring electrodes 110b to 110d, except for the wiring electrode 110a for bonding wires. Next, as shown in FIG. 6C, the second FET 202 and the metal piece 107b are connected to the substrate 101. At the time, the second FET 202 is disposed so that the gate electrode 205 and the source electrode 204 respectively overlap the wiring electrodes 110c and 110d via the first conductive connecting members 103. Further, the metal piece 107b is disposed so as to overlap the wiring electrode 110b via the first conductive connecting member 103.

Next, as shown in FIG. 6D, a first conductive connecting members 103 are applied on the upper surfaces of the metal piece 107b and the second FET 202. Next, as shown in FIG. 6E, the VCSEL 105 mounting the first FET 201 is connected to the upper surfaces of the metal piece 107b and the second FET 202. Finally, as shown in FIG. 6F, the VCSEL module 100 is heated to cure the first conductive connecting members 103. At the time, the second conductive member 107c is formed.

In the VCSEL module 100 in which the second conductive member 107 includes the solder ball 107a, since the second conductive member 107 is connected to the cured first conductive connecting member 103 on the wiring electrode 110b by melting the solder ball 107a, the temperature profile is complicated, and therefore manufacturing conditions are difficult. In contrast, in the VCSEL module 130, since the first conductive connecting member 103 is connected to the metal piece 107b by only curing the first conductive connecting members 103, the temperature profile of the VCSEL module 130 is simplified. Since it is sufficient to mainly consider only the curing of the first conductive members 103 during the heating, the manufacturing conditions are facilitated. Further, in the process shown in FIG. 6C, since the metal piece 107b is disposed with the second FET 202, an increasing load in the process is slight. Since variations in shape of the metal piece 107b is smaller than that of the solder balls 107, the manufacturing process are further facilitated.

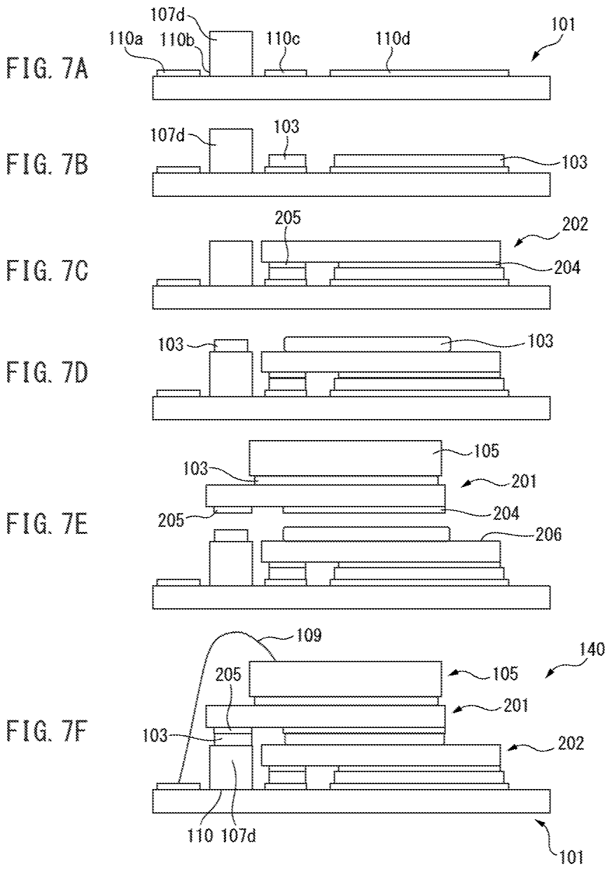

FIG. 7 is a diagram explaining for a VCSEL module 140 according to a second modification of the VCSEL module 100 and a manufacturing method thereof. Side views of a characteristic states in each step are shown in FIGS. 7A to 7F. Members such as a capacitor 113 (refer to FIG. 3), except for the VCSEL 105, the first and second FETs 201 and 202 and members relating to the VCSEL 105 are not illustrated in FIG. 7A to 7F. An optical element and a frame that may be added are not shown therein.

The second conductive member 107 including the solder ball 107a is utilized in the VCSEL module 100, and the second conductive member 107c including the metal piece 107b is utilized in the VCSEL module 130. However, the second conductive member 107 is not necessarily required to connect the gate electrode 205 of the first FET 201 and the wiring electrode 110b of the substrate 101. The VCSEL module 140 without using the second conductive members 107 and 107b and etc., will be explained.

First, the construction of the VCSEL module 140 will be explained with reference to FIG. 7F. As shown in FIG. 7F, the VCSEL module 140 includes the second FET 202, the first FET 201 and the VCSEL 105 stacked on the substrate 101 in the order from the lower side in FIG. 7F. The thick copper plating layer 107 is formed on an upper portion of the wiring electrode 110b, and the gate electrode 205 of the first FET 201 is connected to the wiring electrode 110b via the first conductive connecting member 103 and the wiring electrode 107d. Comparing FIG. 7F and FIG. 1, the structure of the VCSEL module 140 is common to that of the VCSEL module 100, and only the structure connecting the gate electrode 205 and the wiring electrode 110b of the first VCSEL are different from those of the VCSEL module 100. Similarly to the VCSEL module 100, the first FET 201 is not necessarily required for the VCSEL module 140.

First, as shown in FIG. 7A, the substrate 101 having a wiring electrodes 110a to 110d and etc., on the upper surface is prepared. The wiring electrode 110b includes a thick copper plating layer 107d formed by a plating method on the upper portion thereof, and the thickness of the wiring electrode 110b is thicker than those of the other wiring electrodes 110a, 110c and 110d. Next, as shown in FIG. 7B, the first conductive connecting members 103 are applied on the upper surfaces of the wiring electrodes 110c and 110d, except for the wiring electrode 110a for bonding wires and the wiring electrode 110b including the thick copper plating layer 107d. Next, as shown in FIG. 7C, the second FET 202 is connected to the substrate 101. At the time, the second FET 202 is disposed so that the gate electrode 205 and the source electrode 204 respectively overlap the wiring electrodes 110c and 110d via the first conductive connecting members 103.

Next, as shown in FIG. 7D, the first conductive connecting members 103 are applied on the upper surfaces of the thick copper plating layer 107d and the second FET 202. Next, as shown in FIG. 7E, the first FET 201 mounting the VCSEL 105 is connected to the upper surfaces of the thick copper plating layer 107d and the second FET 202. Finally, as shown in FIG. 7F, the VCSEL module 140 is heated to cure the first conductive connecting members 103. At the time, the gate electrode 205 is connected to the wiring electrode 110b of the second FET 202.

The manufacturing process of the VCSEL module 140 shown in FIGS. 7B to 7F is more simplified than those of the VCSEL module 130 shown in FIGS. 6B to 6F. The step of forming the second conductive member 107c is omitted from the manufacturing process of the VCSEL module 140.

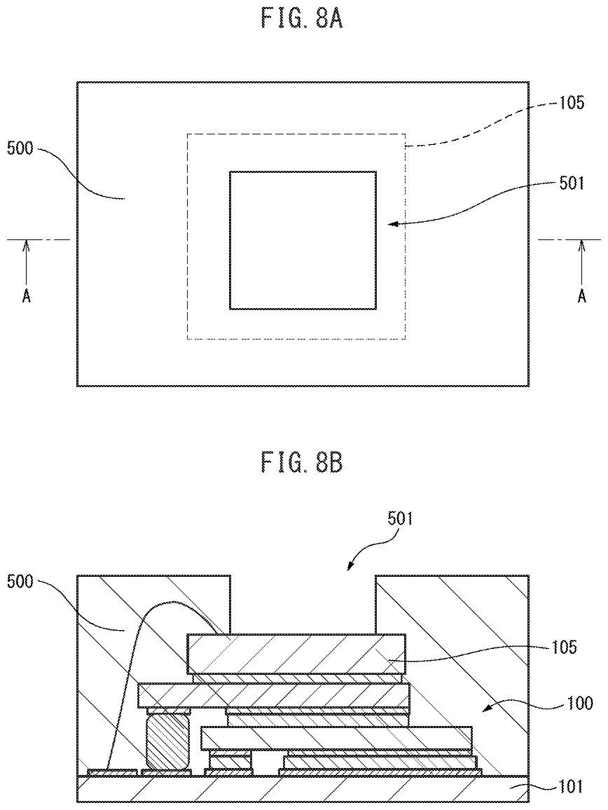

FIG. 8 is a diagram illustrating the VCSEL module 100 with a first frame 500. FIG. 8A shows a top view, and FIG. 8B is a sectional view along A-A of FIG. 8A.

The first frame 500 is a member made of a black resin, and is disposed on the upper portion of the substrate 101 so as to cover the entire VCSEL module 100 except for a portion where a part of the VCSEL 105 is exposed from a central opening 501. The VCSEL module 100 is suitable for long-term use, since environmental resistance is improved by covering the VCSEL module 100 by the first frame 500. Light emitted from VCSEL 105 is emitted to an external through the opening 501.

An optical element having a predetermined optical property may be disposed so as to cover the opening 501. For example, a thermoplastic resin such as a polyarylate resin, a thermosetting resin such as a silicone resin, and a light transmissive member formed of an ultraviolet curable resin such as an epoxy resin may be utilized as the optical element. Light having a desired light distribution may be emitted by forming and uniformizing the light emitted from VCSEL 105 with an optical elements.

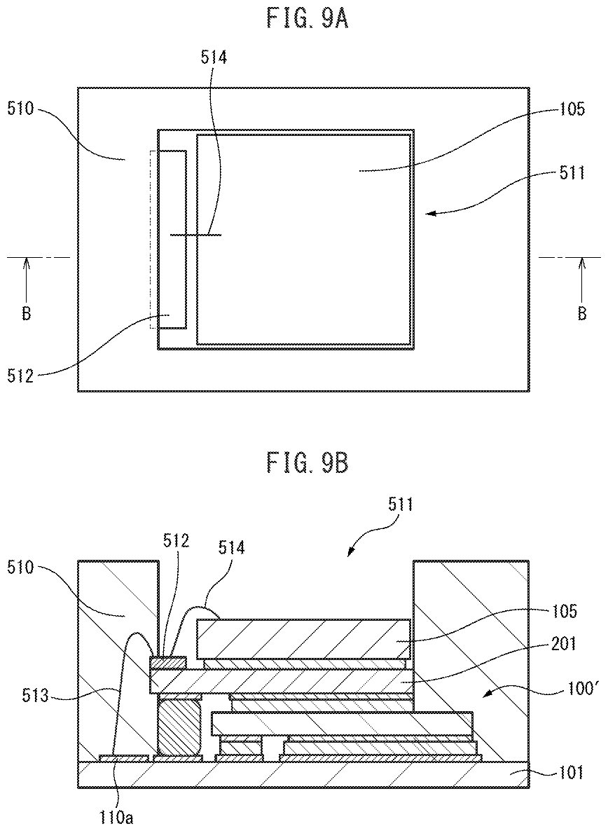

FIG. 9 is a diagram illustrating a VCSEL module 100′ with a second frame 510. FIG. 9A shows a top view, and FIG. 9B is a sectional view along B-B of FIG. 9A. The VCSEL module 100′ is different from the VCSEL module 100 in that the VCSEL module 100′ includes the relay electrode 512 disposed on the upper surface of the first FET 201, the first bonding wire 513 and the second bonding wire 514, instead of the bonding wire 109 and elements in the VCSEL module 100 except for the relay electrode 512, first bonding wire 513 and second bonding wire 514 are the same as those of the VCSEL module 100. The wiring electrode 110a and the relay electrode 512 are connected by the first bonding wire 513, the relay electrode 512 and the anode of the VCSEL 105 are connected by the second bonding wire 514.

The first frame 510 is a member made of a black resin, and is disposed on the upper portion of the substrate 101 so as to cover the VCSEL module 100′ except for a portion where the entire VCSEL 105 and a part of relay electrode 512 is exposed from a central opening 511. The VCSEL module 100′ is suitable for long-term use, since environmental resistance is improved by covering the VCSEL module 100′ by the first frame 510. Light emitted from the VCSEL 105 is emitted to an external through the opening 511. An optical element having a predetermined optical characteristic may be disposed so as to cover the opening 511, as shown in FIG. 8.

Since the opening area of the opening 511 in FIG. 9 is large, VCSEL 105 may be mounted and be connected with the second bonding wire 514, after the VCSEL module 100′ except for the VCSEL 105 and second bonding wires 514 is covered with the frame 510. The degree of freedom in design is increased.

In the VCSEL module according to embodiments, a VCSEL module may be provided, in which even if a pulse current flowing through Vertical Cavity Surface Emitting Laser (VCSEL) as a light source that surface emits light in a direction perpendicular to a mounting surface has an extremely short width, the rising time in the waveform of the pulse current is within 1 (ns) or less, and therefore a waveform of the pulse current is nearly a square wave.

A VCSEL module according to an embodiment includes a VCSEL, a first FET disposed below VCSEL, and a second FET disposed below the first FET, and one of the first FET and second FET is a switching element, and the other thereof is a current control element.

In the above VCSEL module, the VCSEL, the switching element and the current control element form a four stage stacked structure. In the VCSEL included in the VCSEL module, a substantially linearly current flows from an anode on an upper surface to a cathode on a lower surface. In the first and second FETs used as the switching element and the current control element, a substantially linearly current flows from a drain electrode on an upper surface to a source electrode on an lower surface. In the stacked structure including VCSEL and the first and second FETs, the linearly currents flow from an upper portion to a lower portion. Therefore, in the stack structure, inductance is minimized since the current path is linear and short. Further, in the stack structure, since the current control element is disposed in the current path, the current does not continue to rise during a short period given by the pulse width.

Further, in the above VCSEL module, a capacitor for supplying a current to VCSEL may be disposed.

The above VCSEL module further includes a circuit substrate, and a gate electrode of the first FET and a wiring electrode of the circuit substrate may be connected via a solder ball, a stud bump or a metal piece.

The above VCSEL module further includes a circuit substrate, and a wiring electrode of the circuit substrate connected to a gate electrode of the first FET may be thicker than the other wiring electrodes formed on the circuit substrate.

Further, in the above VCSEL module, since inductance of a current path including VCSEL is minimized, a rise time of the pulse current flowing through the VCSEL is within 1 (ns) or less, and a waveform of the pulse current is nearly a square wave during a short time given by a width of a pulse current flowing through the VCSEL.

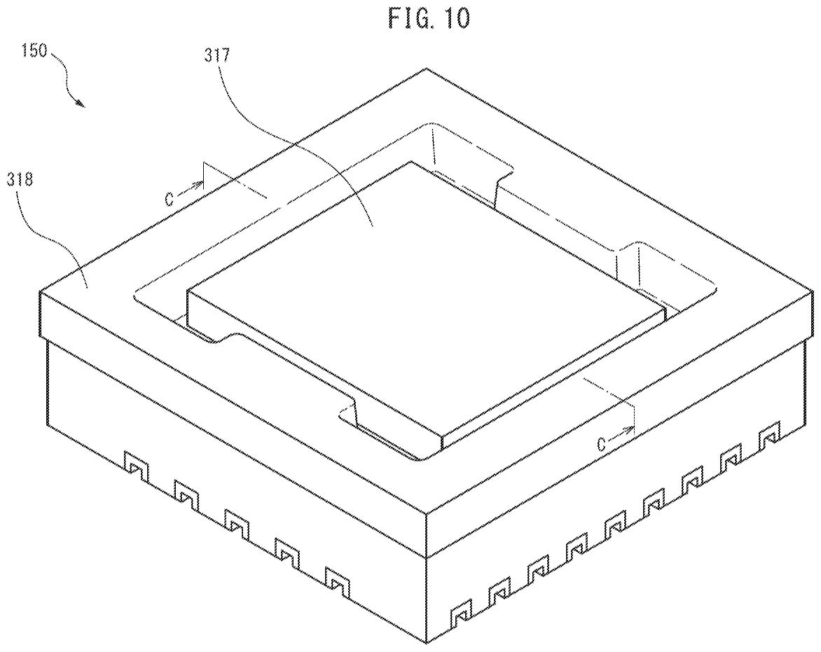

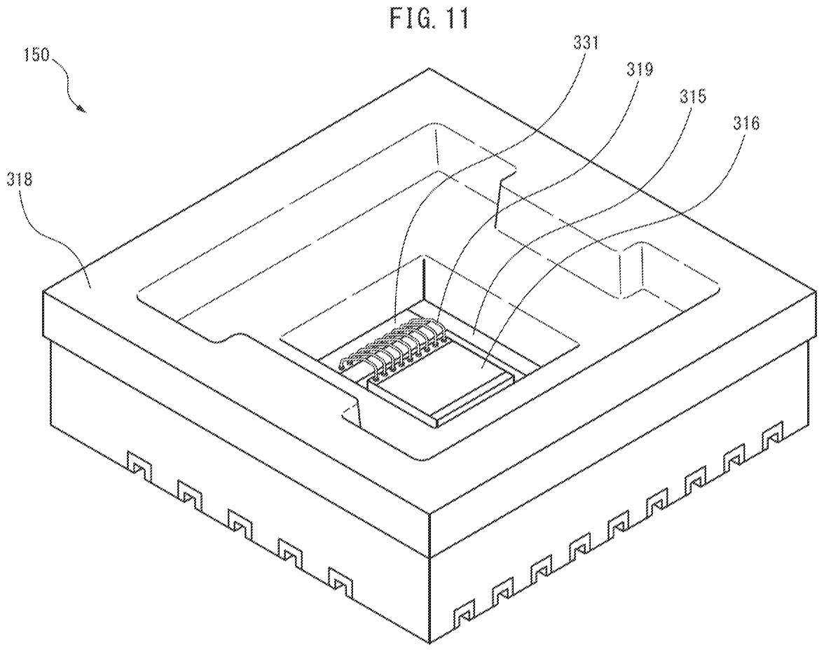

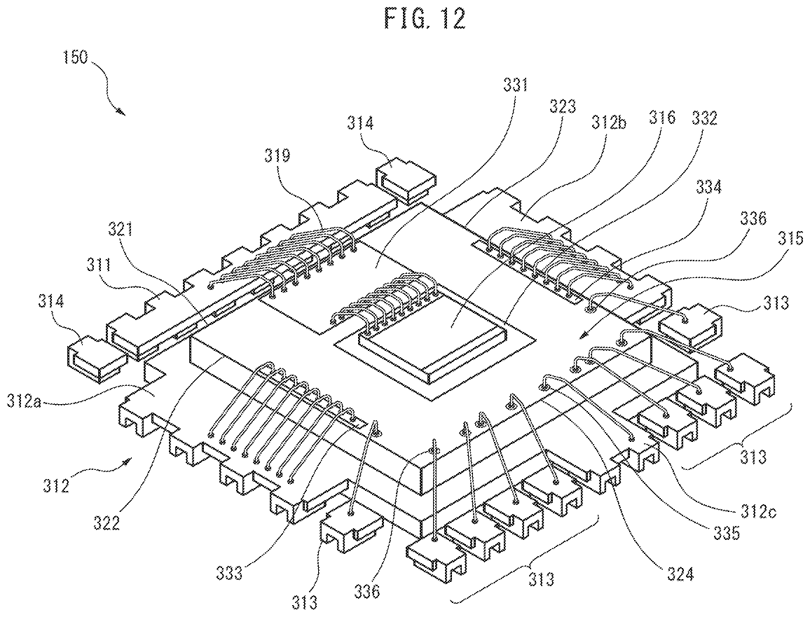

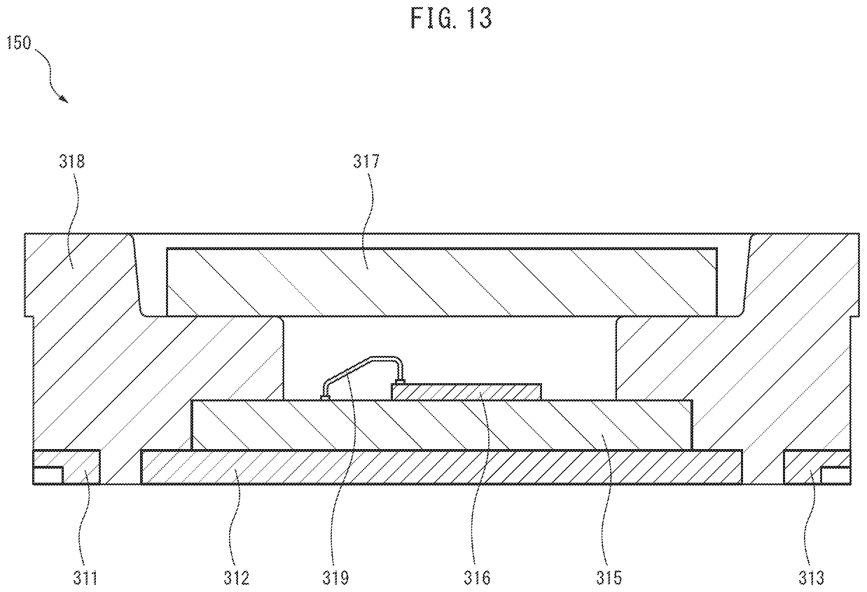

FIG. 10 is a perspective view of a VCSEL module 150 according to the second embodiment, FIG. 11 is a perspective view of the VCSEL module 150 shown in FIG. 10 excluding the optical elements, FIG. 12 is a perspective view of the VCSEL module 150 shown in FIG. 10 excluding the optical elements and the frame, and FIG. 13 is a cross sectional view of the VCSEL module 150 along C-C shown in FIG. 10.

The VCSEL module 150 is a lead frame package, and includes a first electrode 311, a second electrode 312, nine monitor and control electrodes 313, a pair of dummy electrodes 314, a semiconductor device 315, a VCSEL 316, an optical element 317, a frame 318 and a plurality of bonding wires 319. In the VCSEL module 150, the second electrode 312, the semiconductor device 315 and VCSEL 316 are disposed with overlapping. The semiconductor device 315 has a rectangular planar shape, and has a first side 321, a second side 322, a third side 323 and a fourth side 324.

Each of the first electrode 311, the second electrode 312, the nine monitor and control electrodes 313 and the pair of dummy electrodes 314 is formed of a conductive member having high heat dissipation such as aluminum and copper, and are spaced apart from each other. The number of electrodes is an example, not limited to the above. The first electrode 311 has a substantially rectangular planar shape, and is disposed so as to extend a longitudinal direction thereof parallel to an extending direction of the first side 321 of the semiconductor device 315 having a rectangular planar shape. The first electrode 311 is electrically connected to an anode of VCSEL 316 via a first terminal 331 disposed on the surface of the semiconductor device 315 via a plurality of bonding wires 319 disposed along the extending direction of the first side 321.

The semiconductor device 315 is mounted on a second electrode 312 including a the first protruding portion 312a, a second protruding portion 312b and a third protruding portion 312c, and is disposed close to each of the second side 322, the third side 323 and the fourth side 324 of the semiconductor device 315. The second electrode 312 is electrically connected to the semiconductor device 315 via a plurality of bonding wires 319, and one end of each of the plurality of bonding wires 319 is connected to first protruding portion 312, second protruding portion 312b and third protruding portion 312c. The second electrode 312 is thermally connected to the semiconductor device 315 via adhesive member having high thermal conductivity such as a resin material containing a metal.

Five monitor and control electrodes 313 of the nine monitor and control electrodes 313 are disposed along the second side 322 and the fourth side 324 of the semiconductor device 315 between the first protruding portion 312a and the third protruding portion 312c. The other four monitor and control electrodes 313 of the nine monitor and control electrode 313 are disposed along the third side 323 and the fourth side 324 of the semiconductor device 315 between the second protruding portion 312b and the third protruding portion 312c. Each of the nine monitor and control electrodes 313 is electrically connected to the semiconductor device 315 via a bonding wire 319.

The pair of dummy electrodes 314 are spaced apart from the first electrode 311 at each of the longitudinal direction ends of the first electrode 311.

The semiconductor device 315 includes a first terminal 331, a second terminal 332, a third terminal 333, a fourth terminal 334, a fifth terminal 335, and nine monitor and control terminals 336, and monitors and controls a driving current flowing between an anode and a cathode of the VCSEL 316.

The first terminal 331 has a rectangular planar shape, and is disposed on the surface of the semiconductor device 315 along the first side 321 facing the first electrode 311. The length of the side of the first terminal 331 along the first side 321 facing the first electrode 311 is preferably longer than that of a side along the first side 321 facing the first electrode 311 of the VCSEL 316. The number of wires from the anode disposed in substantially all of the at least one side of the VCSEL 316 may be maximized, and therefore the voltage drop by the wiring resistor is suppressed. Further, the length of a side perpendicular to the first side 321 facing the first electrode 311 of the first terminal 331 is preferably shorter than a side along the first side 321 facing the first electrode 311 of the VCSEL 316. Since a current path through the first terminal 331 is shortened, and a voltage drop by wiring resistance is suppressed. The length of a side of the first terminal 331 perpendicular to the first side 321 facing the first electrode 311 is determined by a sizes of the semiconductor device 315 and the VCSEL 316, and may be equal to or longer than the sides along the first side 321 facing the first electrode 311. In a region of the first terminal 331 proximate to the first side 321, the plurality of bonding wires 319 for electrically connecting between the first electrode 311 and the first terminal 331 are disposed along the extending direction of the first side 321. In a region of the first terminal 331 spaced from the first side 321, the plurality of bonding wires 319 for electrically connecting between the first electrode 311 and the anode of the VCSEL 316 are disposed along the extending direction of the first side 321.

The second terminal 332 has a rectangular planar shape, and is disposed at the center of the surface of the semiconductor device 315. The VCSEL 316 is mounted on the second terminal 332, and the second terminal 332 electrically connects to the cathode of VCSEL 316.

Each of the third terminal 333 and the fourth terminal 334 has a rectangular planar shape having longitudinal directions extending along the second side 322 and the third side 323 perpendicular to the first side 321, and is disposed on the surface of the semiconductor device 315 along each of the second side 322 and the third side 323. The plurality of bonding wires 319 for electrically connecting between the first protruding portion 312a and the third terminal 333 are disposed on the third terminal 333 along the extending direction of the second side 322. The plurality of bonding wires 319 for electrically connecting between the second protruding portion 312b and the fourth terminal 334 are disposed on the fourth terminal 334 along the extending direction of the third side 323.

The fifth terminal 335 has a rectangular planar shape, and is disposed close to the central portion of the fourth side 324. The bonding wire 319 for electrically connecting between the third protruding portion 312c and the fifth terminal 335 is disposed on the fifth terminal 335.

Each of the nine monitor and control terminals 336 has a rectangular planar shape, and are disposed close to the second side 322, third side 323 and fourth side 324. The bonding wires 319 for electrically connecting the nine monitor and control electrodes 313 are disposed on each of the nine monitor and control terminals 336.

The semiconductor device 315 is a one side wiring substrate capable of complicated circuit configuration, and has a high degree of freedom in wiring design. The degree of freedom in the wiring design means that the wiring may have a width of 1 μm or more, 5 μm or more, or 10 μm or more, and narrower than 50 μm or less, 100 μm or less, or 200 μm, and may have a pitch of 1 μm or more, 5 μm or more, or 10 μm or more, and narrower than 50 μm or less, 100 μm or less, or 200 μm. Further, for example, the first terminal 331, the second terminal 332, the third terminal 333, the fourth terminal 334, the fifth terminal 335 and nine monitor and control terminals 336 may be easily disposed on preferred positions of each side of the semiconductor device 315. The first electrode 311, the second electrode 312, the monitor and control electrodes 313 and the dummy electrode 314 may be easily disposed close to each of terminals so that the wire lengths are shortest, and the chance for breaking of the bonding wires 319 is reduced, since the wire length between each terminal and each electrode may be shortest. Further, since the arrangement of each electrode is easy, a lead frame having low degree of freedom in wiring design may be used. The low degree of freedom in the wiring design means that for example, the width of the wiring is 200 μm or more, or 300 μm or more, and the pitch of the wiring is 200 μm or more. The lead frame, for example, may be a metal material such as copper, be a single material or single layer of a metal material, and plating such as gold and silver, and be formed over the entire circumference of the surface of the lead frame.

A plurality of emitters emitting a laser beam are arranged in arrays at equal intervals on the surface of the VCSEL 316. The VCSEL 316 has, for example, 364 (26×14) emitters, and the 364 emitters are arranged at 0.0385 mm pitches. The VCSEL 316 has the anode disposed on the front surface and the cathode disposed on the lower surface, and emits light in response to a current supply between the anode and the cathode.

The optical element 317 is a light transmissive member formed of, for example, a thermoplastic resin such as a polyarylate resin, a thermosetting resin such as a silicone resin, and an ultraviolet curable resin such as an epoxy resin. A diffusion surface which is embossed and etc., for diffusing the light emitted from VCSEL 316 is formed at least one of the upper surface and lower surface of the optical element 317. The optical element 317 shapes and uniformizes light emitted from the VCSEL 316 to emit light having a desired light distribution. It is preferable for the optical device 317 to be made of a material that transmits light emitted from the VCSEL 316 so as not to reduce the luminous efficacy of the VCSEL module 150. The transmittance of the optical element 317 is preferably 90% or more, more preferably 95% or more.

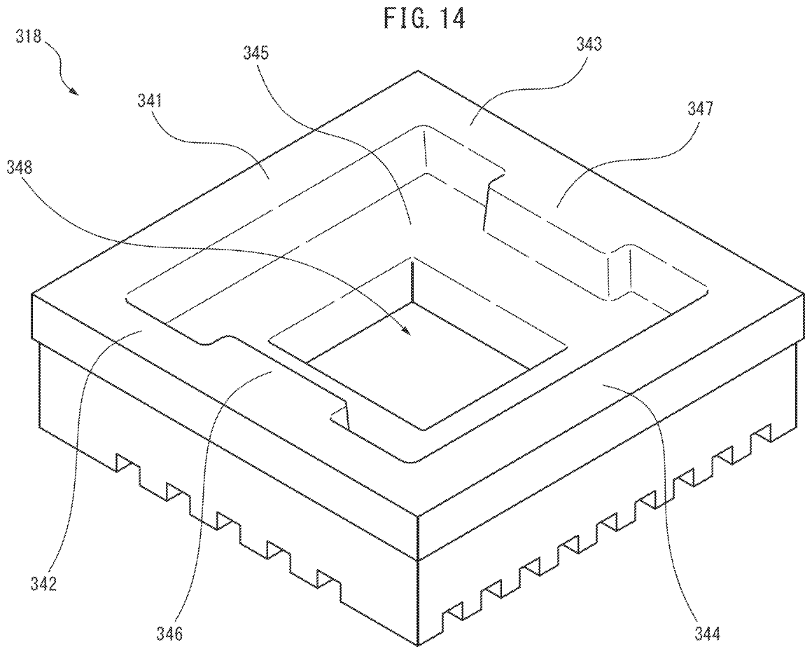

FIG. 14 is a perspective view of the frame 318.

The frame 318 is a member made of a black resin, and includes a first wall 341, a second wall 342, a third wall 343, a fourth wall 344, a support surface 345, a first convex portion 346 and a second convex portion 347. The frame 318 is disposed so as to cover the surface of the first electrode 311 and the second electrode 312, and a portion of the first terminal 331, and the third terminal 333 and the fourth terminal 334. The lower surfaces of the first electrode 311, the second electrode 312, the monitor and control electrodes 313 and the dummy electrodes 314 are not covered by the frame 318. The lower surface of the frame 318 forms the same surface as those of the first electrode 311, the second electrode 312, the monitor and control electrodes 313 and the dummy electrodes 314. The lower surfaces of the first electrode 311, the second electrode 312, the monitor and control electrode 313 and the dummy electrode 314, for example, may be surfaces in contact with the heat sink (not shown), and may have a large heat dissipation path.

Each of the first wall 341, the second wall 342, the third wall 343 and the fourth wall 344 extends parallel to each of the first side 321, the second side 322, the third side 323 and the fourth side 24 of the semiconductor device 315. The support surface 345 is surrounded by the first wall 341, the second wall 342, the third wall 343 and the fourth wall 344, and a rectangular opening 348 through which the VCSEL 316 is visually recognized is formed in the center of the support surface 345.

The first convex portion 346 is disposed in the central portion of the inner wall of the second wall 342 so as to protrude in the direction of the third wall 343 facing the second wall 342. The second convex portion 347 is disposed in the central portion of the inner wall of the third wall 343 so as to protrude in the direction of the second wall 342 facing the third wall 343. Each of the first convex portion 346 and the second convex portion 347 is disposed so as to face an end of the optical element 317.

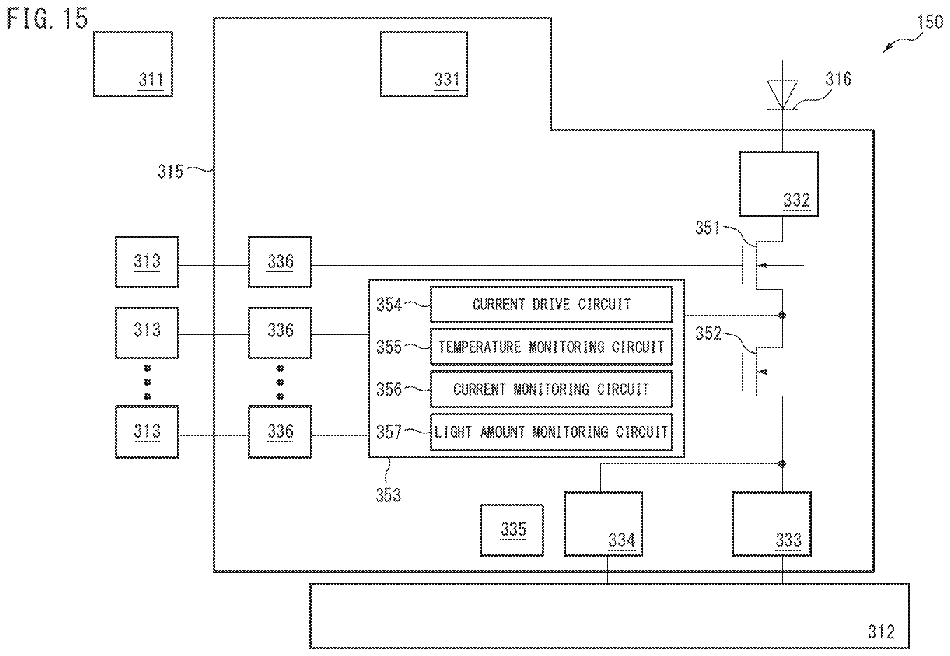

FIG. 15 is a circuit diagram of the VCSEL module 150.

The semiconductor device 315 further includes a current control element 351, a switching element 352 and a monitor and control circuit 353. The semiconductor device 315 controls the current control element 351 and the switching element 352 connected in series to VCSEL 316, and monitors and controls the emission of the VCSEL 316 by monitoring a current and etc., flowing through the monitor and control circuit 353 to the VCSEL 316.

Each of the current control element 351 and the switching element 352 is an n-type metal oxide semiconductor field effect transistor (Metal-Oxide-Semiconductor Field Effect Transistor, MOSFET). The current control element 351 and the switching element 352 are connected to the second terminal 332, the third terminal 333 and the fourth terminal 334 via the VCSEL 316, the current control element 351 controls the amount of the driving current, and the switching element 352 is a drive element for controlling the switching between on and off of the driving current.

A gate of the current control element 351 is connected to one of the monitor and control electrodes 313 via one of the monitor and control terminals 336. A source of the current control element 351 is connected to a drain of the switching element 352, and a drain of the current control element 351 is connected to the cathode of VCSEL 316 via the second terminal 332. A gate of the switching element 352 is connected to the monitor and control circuit 353, and a source of the switching element 352 is connected to the second electrode 312 via the third terminal 333 and the fourth terminal 334.

The current control element 351 controls the amount of the driving current flowing between the anode of the VCSEL 316 (also referred to as a VCSEL first terminal) and the cathode (also referred to as a VCSEL second terminal) and between the source and drain of the current control element 351 based on a current setting signal applied to the monitor and control electrode 313.

The switching element 352 turns on and turns off the driving current flowing between the anode and the cathode of VCSEL 316 and between the source and drain of the switching element 352 in a predetermined period, by turning on and turns off based on a periodic signal generated by the monitor and control circuit 353.

The monitor and control circuit 353 includes a current drive circuit 354, a temperature monitoring circuit 355, a current monitoring circuit 356 and a light amount monitoring circuit 357. The current drive circuit 354 generates a periodic signal based on a signal input from the monitor and control electrode 313 via the monitor and control terminals 336, and applies the generated periodic signal to the gate of the switching element 352. A power supply voltage is supplied from the monitor and control terminals 336 to the monitor and control circuit 353, and the monitor and control circuit 353 is grounded by connected to the second electrode 312 via the fifth terminal 335.

The temperature monitoring circuit 355 has a thermistor, measures a temperature of the VCSEL 316 disposed on the surface of the semiconductor device 315, and when a temperature measured by the thermistor exceeds a predetermined threshold temperature, the temperature monitoring circuit 355 outputs an alarm signal outputs from the monitor and control electrode 313 via the monitor and control terminals 336. A light amount signal indicating the amount of light emitted from VCSEL 316 is input to the light amount monitoring circuit 357 from the photoelectric conversion element (not shown), and when the amount of light corresponding to the input light amount signal deviates from a predetermined light amount range, and outputs an alarm from the monitor and control electrode 313 signal via the monitor and control terminals 336. In the VCSEL module 150, although it is not necessary for the monitor and control circuit 353 to include all of the current drive circuit 354, the temperature monitoring circuit 355, the current monitoring circuit 356 and the light amount monitoring circuit 357, it is preferable for the monitor and control circuit 353 to includes at least one of them.

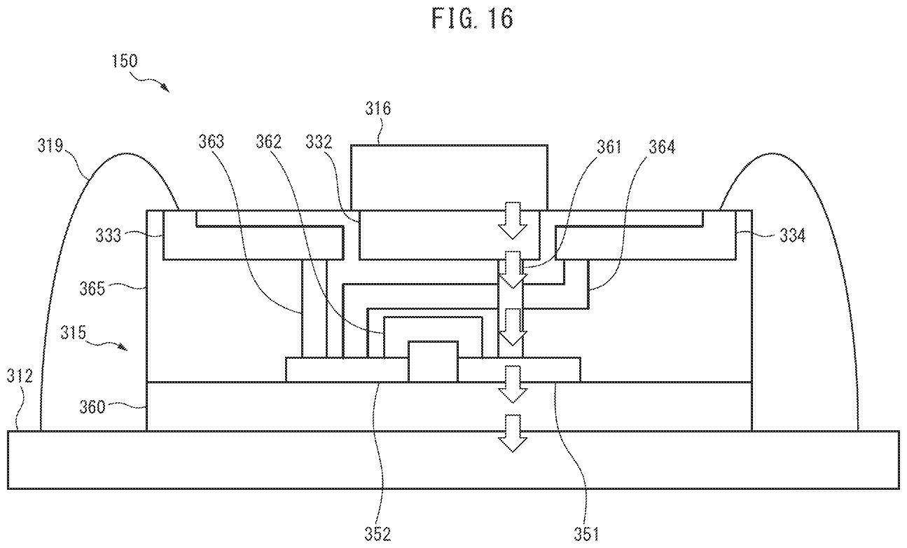

FIG. 16 is a diagram illustrating a connecting relationship among the second electrode 312, the semiconductor device 315 and the VCSEL 316.

The semiconductor device 315 further includes a silicon substrate 360, a first wiring layer 361, a second wiring layer 362, a third wiring layer 363, a fourth wiring layer 364 and an insulating layer 365. P-type semiconductors in which boron and etc., are doped, n-type semiconductors in which phosphorus and etc., are doped and etc., are formed on the surface of the silicon substrate 360. The p-type semiconductors and n-type semiconductors formed on the surface of the silicon substrate 360 form semiconductor elements included in each of the current control element 351, and the switching element 352 and the monitor and control circuit 353.

Each of the first wiring layer 361 to the fourth wiring layer 364 includes a plurality of wiring layers formed by a conductive member such as aluminum and inter-layer connection portions, also referred to as vias, for connecting among a plurality of wiring layers. The first wiring layer 361 electrically connects between the second terminal 332 and the current control element 351, and the second wiring layer 362 electrically connects between the current control element 351 and the switching element 352. The third wiring layer 363 electrically connects between the third terminal 333 and the switching element 352, and the fourth wiring layer 364 electrically connects between the fourth terminal 334 and the switching element 352. The insulating layer 365 is a silicon oxide film, and insulates among the respective layers of the first wiring layer 361 to the fourth wiring layer 364. In FIG. 16, although the insulating layer 365 is thicker than the silicon substrate 360 for the purpose of explanation of the layer structure, the insulating layer 365 is actually a thin film having a thickness of several 1000 Å, and the silicon substrate 360 has a thick structure having a thickness of 200 μm.

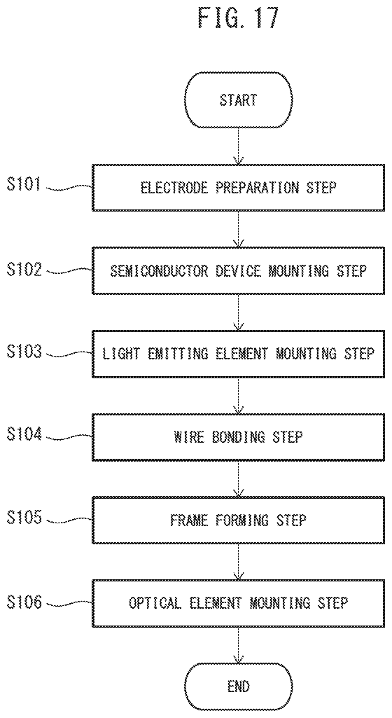

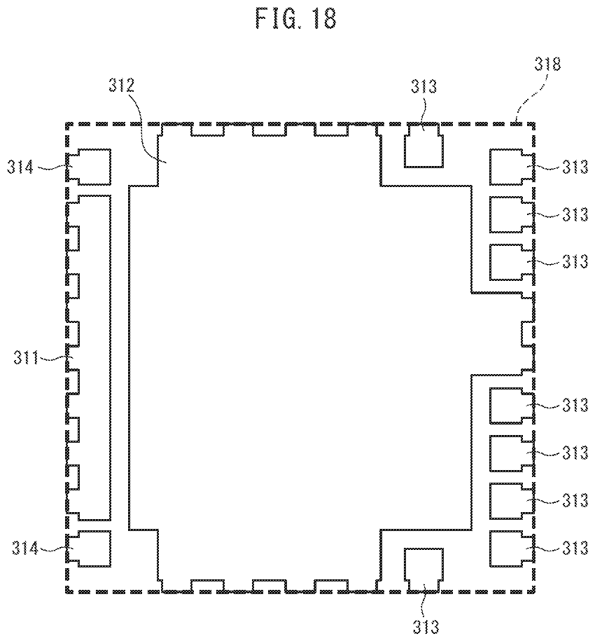

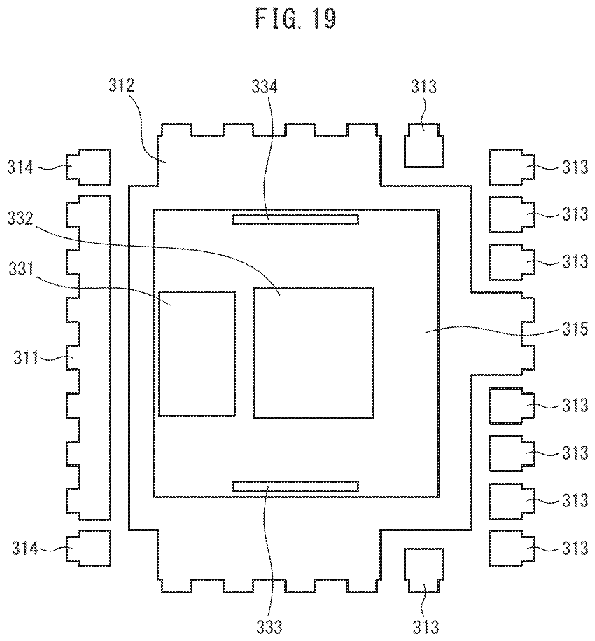

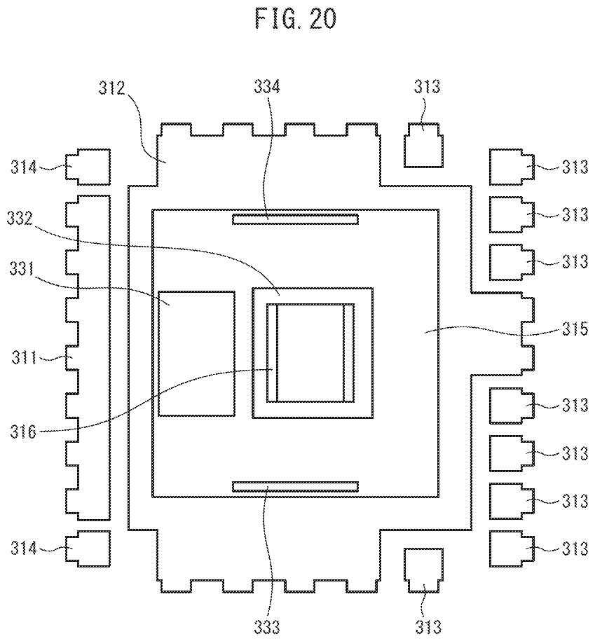

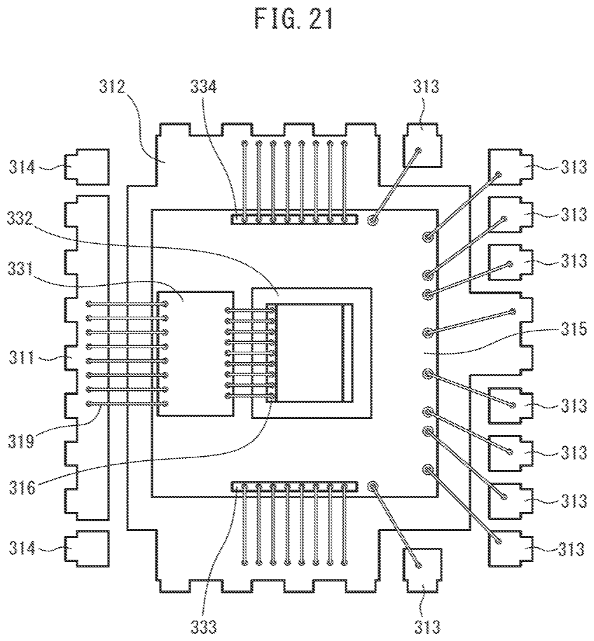

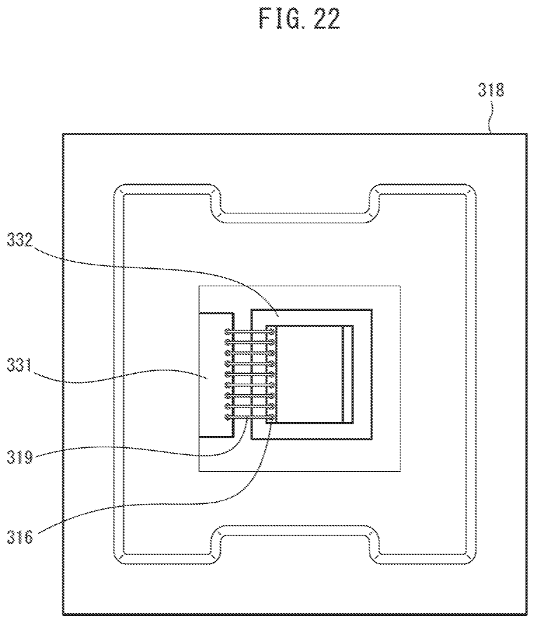

FIG. 17 is a flow chart illustrating manufacturing methods for the VCSEL module 150. FIG. 18 is a planar view corresponding to an electrode preparation step shown in FIG. 17, FIG. 19 is a plan view corresponding to a semiconductor device mounting step shown in FIG. 17, and FIG. 20 is a plan view corresponding to a light emitting element mounting step shown in FIG. 17. FIG. 21 is a planar view corresponding to a wire bonding step shown in FIG. 17, and FIG. 22 is a plan view corresponding to a frame forming step shown in FIG. 17. Although FIGS. 17 to 22 illustrate a manufacturing method in which a single VCSEL module 150 is manufactured, a plurality of VCSEL modules 150 may be simultaneously manufactured by a manufacturing method similar to the manufacturing method described with reference to FIGS. 17 to 22, and subsequently individualized.

First, as shown in FIG. 18, in the electrode preparation step, each of the first electrode 311, the second electrode 312, the plurality of monitor and control electrodes 313 and the pair of dummy electrodes 314 is disposed at a predetermined position spaced from each other (S101). In FIG. 18, the outer shape of the frame 318 added in the frame forming step is shown by a dotted line.

Next, as shown in FIG. 19, in the semiconductor device mounting step, the semiconductor device 315 is mounted on the second electrode 312 (S102). The semiconductor device 315 is mounted on the second electrode 312, by adhering to the surface of the second electrode 312 via a conductive connecting member having high thermal conductivity such as a resin material containing a metal.

Next, as shown in FIG. 20, in the light emitting device mounting step, the VCSEL 316 is mounted to the second terminal 332 disposed on the surface of the semiconductor device 315 (S103). The cathode of VCSEL 316 is electrically connected to the second terminal 332, by adhering to the surface of the second terminal 332 via a conductive connecting member such as gold-tin solder. The VCSEL 316 is disposed by overlapping on the second electrode 312 and the semiconductor device 315.

Next, as shown in FIG. 21, in the wire bonding step, bonding wires 319 electrically connect between the electrodes such as the first electrode 311 and the terminals such as the first terminal 331, and between the first terminal 331 and the anode of the VCSEL 316 (S104). The semiconductor device 315 and VCSEL 316 are electrically connected to an external device, by electrically connecting between the electrodes such as the first electrode 311 and the terminals such as the first terminal 331, and between the first terminal 331 and the anode of the VCSEL 316 by bonding wires 319.

Next, as shown in FIG. 22, in the frame forming step, the frame 318 is formed so as to cover the surfaces of the first electrode 311 and the second electrode 312, a portion of the first terminal 331, and the third terminal 333 and the fourth terminal 334 (S105). The frame 318 is formed by heating and solidifying a raw material of the frame 318 after the raw material of the frame 318 is injected into a mold having a shape corresponding to a shape of the frame 318.

Next, in the optical element mounting step, the optical element 317 is mounted on the support surface 345 of the frame 318 (S106), and the VCSEL module 150 is formed. The optical element 317 is mounted on the support surface 345 by bonding to the support surface 345 via an adhesive formed of a resin material such as a silicone resin.

In the VCSEL module 150, since the VCSEL 316 is disposed so as to overlap on the semiconductor device 315 that is a driving device for driving VCSEL 316, the semiconductor device 315 and VCSEL 316 are integrated, and therefore the VCSEL module 150 may be miniaturized. Further, in the VCSEL module 150, since the VCSEL 316, the semiconductor device 315 for driving (switching) VCSEL 316, and the second electrode 312 for grounding the semiconductor device 315 have a structure stacked in three stages (three stage stacked structure), the VCSEL module 150 may be further miniaturized.

In the VCSEL module 150, since heat radiated from the VCSEL 316 during light emission is dissipated through the semiconductor device 315 to the second electrode 312 which is formed of a material having high thermal conductivity, and the VCSEL module 150 has good heat dissipation properties. As shown by the direction of arrow in FIG. 16, heat radiated from the VCSEL 316 is radiated to the second electrode 312 through the second terminal 332, the first wiring layer 361, the insulating layer 365 and the silicon substrate 360 on which the current control element 351 and the switching element 352 is formed. Since the thermal conductivity of the silicone substrate 360 which serves as a main component is 160 W/mK and high, good heat dissipation may be achieved. Further, although the thermal conductivity of the insulating layer 365 is lower than that of the silicon substrate 360, the insulating layer 365 is as thin as several 1000 Å as explained above, and the heat dissipation property is not affected.

In the VCSEL module 150, the plurality of bonding wires 319 connect between the first electrode 311 and the first terminal 331. For example, if the VCSEL 316 is mounting on the first terminal 331, the lengths of the bonding wires 319 are increased by a distance spaced apart, when the bonding wires 319 are disposed at a position spaced from the upper end of the first side 321, so as not to protrude from the first side 321 of the semiconductor device 315. Further, the lengths of the bonding wires 319 are increased by a distance spaced apart, the lengths of the bonding wires 319 are increased by a distance spaced apart, since the bonding wires 319 connecting the VCSEL 316 and the first electrode 311 are separated from the VCSEL 316 so as not to touch the upper end of the first side of the semiconductor device 315. On the other hand, in the VCSEL module 150, the voltage drop by the resistor of the wiring between the first electrode 311 and the first terminal 331 is lower than that in case that the VCSEL 316 is mounted to the first terminal 331, since the bonding wire 319 may be disposed close to the first side 321 of the first terminal 331. For example, if the VCSEL 316 is directly connected to the first electrode 311, the lengths of the bonding wires 319 are increased by a distance spaced apart, since the bonding wires 319 connecting the VCSEL 316 and the first electrode 311 are separated from the VCSEL 316 so as not to touch the upper end of the first side of the semiconductor device 315. On the other hand, in the VCSEL module 150, since the bonding wires 319 are directly connected to the first terminal 331 at a position lower by the height of the VCSEL 316, and connected to the first electrode through the first terminal 331 whose area is large, and whose width is wide, and therefore a wiring resistance is small, the wire path described above compared with the case the first electrode 1 is directly connected to the VCSEL module 150 by the bonding wires 319, the voltage drop by the wiring resistance between the first electrode 311 and the anode of the VCSEL module 150 is suppressed, and the inductance of the wiring is reduced. Further, in VCSEL module 150, since the plurality of bonding wires 319 connect the second electrode 312 to the third terminal 333 and the fourth terminal 334, the voltage rise by the wiring resistance between the second electrode 312 to be grounded and the semiconductor device 315 is suppressed.

In the VCSEL module 150, the first terminal 331 is disposed along the first side 321 facing the first electrode 311, the second terminal 332 is disposed in the center of the surface of the semiconductor device 315, and the third terminal 333 and the fourth terminal 334 are disposed along the second side 322 and the third side 323. In the VCSEL module 150, noises in the driving currents by interfering among the driving currents flowing the first terminal 331, the second terminal 332, the third terminal 333 and the fourth terminal 334 may be reduced, since the first terminal 331, the second terminal 332, the third terminal 333 and the fourth terminal 334 are disposed so as to be spaced apart from each other.

In the VCSEL module 150, noises in the driving currents due to interference between the drive current and signals input and output from the monitor and control circuit 353 may be reduced, since the plurality of monitor and control terminals 336 connected to the monitor and control circuit 353 are disposed along the fourth side 324. Further, noises in the driving current due to interference between the drive current and signals input and output from the monitor and control circuit 353 may be reduced, since the plurality of monitor and control terminals 336 connected to the monitor and control circuit 353 are disposed along the fourth side 324.

In the VCSEL module 150, the surface of the first electrode 311 and the second electrode 312, a portion of the first terminal 331, and the third terminal 333 and the fourth terminal 334 are covered by a resin frame 318 disposed after the wire bonding step. In the VCSEL module 150, since the wire bonding step is performed prior to disposing the frame 318 functioning as the frame member, the size may be reduced without securing the separation in the wire bonding process.

In the VCSEL module 150, since the second electrode 312 and the semiconductor device 315 are fixed by the frame 318, the adhesive strength between the second electrode 312 and the semiconductor device 315 is reinforced by the frame 318, the semiconductor device 315 may be prevented from peeling off from the second electrode 312.

In the VCSEL module 150, the optical element 317 is surrounded by the first wall 341, the second wall 342, the third wall 343 and the fourth wall 344, and is supported by a support surface 345 having an opening 348 from which the VCSEL 316 is visible formed in the center thereof. In the VCSEL module 150, since the optical element 317 is supported by the support surface 345, the size of the optical element 317 whose cost is high may be minimized, and therefore the manufacturing cost of VCSEL module 150 may be reduced.

In the VCSEL module 150, since the frame 318 has a pair of first convex portion 346 and the second convex portion 347 disposed so as to sandwich the optical element 317, the arrangement position of the optical element 317 may be easily determined when the VCSEL module 150 is manufactured.

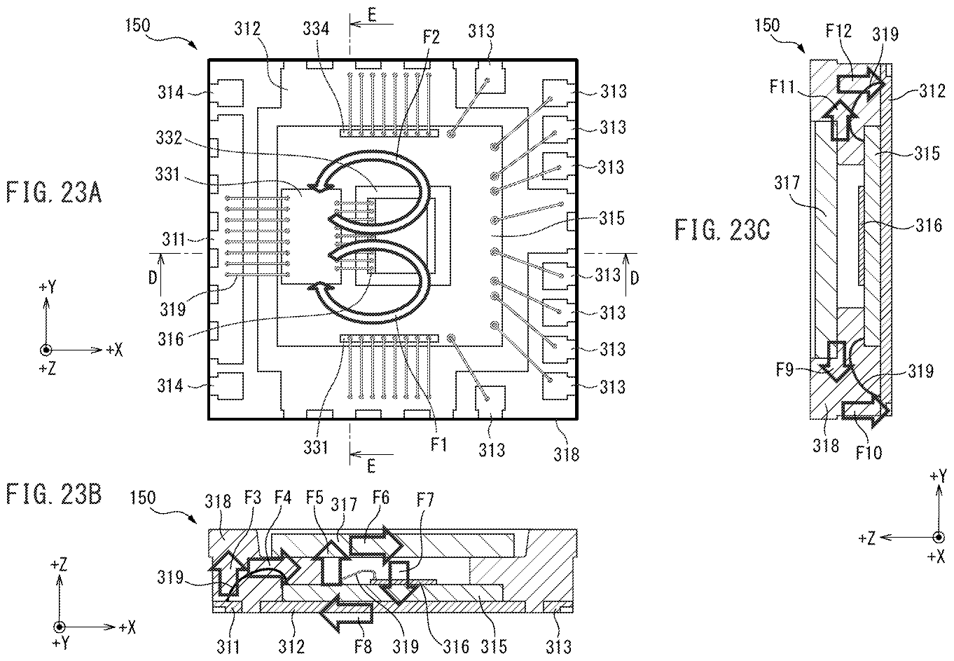

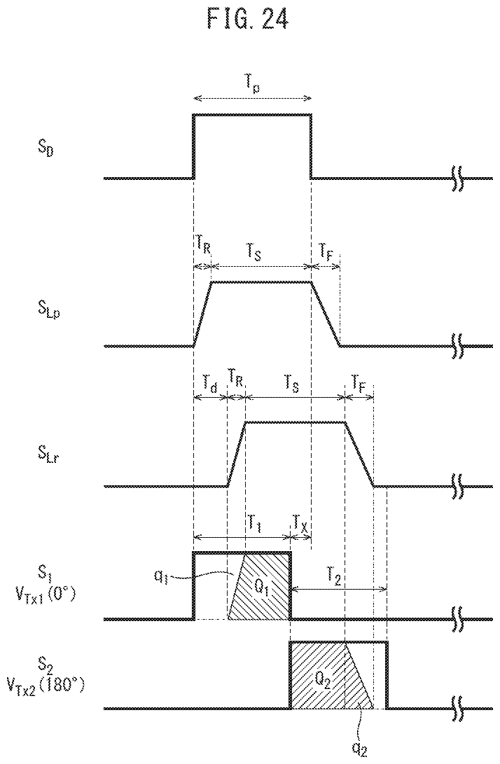

FIG. 23 is a diagram for explaining the flow of currents in the VCSEL module 150. FIG. 23A is a plan view of the VCSEL module 150 except for the base of the frame 318, FIG. 23B is a cross-sectional view of the VCSEL module 150 along D-D of FIG. 23A, and FIG. 23C is a cross-sectional view of the VCSEL module 150 along E-E of FIG. 23A. In FIGS. 23A to 23C, the depth direction of the VCSEL module 150 is a +Z direction, the upward direction in the drawing in FIG. 23A is a +Y direction, and the left direction in the drawing is a +X direction.

As shown in the arrows F3 and F4 in FIG. 23B, the current flowing from the first electrode 311 flows into the first terminal 331 of the semiconductor device 315 via the bonding wires 319 (+X direction from the +Z direction). Next, as shown in the arrows F5 and F6, the current flowing into the first terminal 331 flows into the anode of VCSEL 316 (disposed on the surface of VCSEL 105) through the bonding wires 319 from the first terminal 331 (+X direction from the +Z direction). Next, as shown in the direction of arrow F7, the current flowing into the anode of VCSEL 316 flows from the cathode of VCSEL 316 (disposed on the lower surface of VCSEL 105) to the semiconductor device 315 (−Z direction). Furthermore, the current flowing from the semiconductor device 315 returns to the second electrode 312, and rotates in the direction of the arrow F8 (−X).

As shown in the arrows F9 and F10 in FIG. 23C, the current flowing into the semiconductor device 315 flows from the third terminal 333 via the bonding wire 319 through the current control element 351 and the switching element 352 formed in the semiconductor device 315 to the second electrode 312 (from −Y direction to −Z direction), as shown in the arrows F11 and F12, the fourth terminal 334 of the semiconductor device 315 through the bonding wire 319 flowing to the second electrode 312 (from the +Y direction to −Z direction). The current loop of the direction of arrows F9 and F10 and current loop of the direction of arrows F11 and F12 are symmetrical. As shown in FIG. 23A, a current loop from the left side in the drawing around the lower side (in the direction of arrow F1) is formed, and a current loop from the left side in the drawing around the upper side (in the direction of arrow F2) is formed. In the VCSEL module 150, total inductance may be low, since small current loops are formed in the X-direction, the Y-direction, and the Z-direction in a three-dimensional manner together with a stacked structure.

In the VCSEL module 150, since VCSEL 316, the semiconductor device 315 and the second electrode 312 are stacked in three stages in the Z-direction, the current path flowing out of VCSEL 316 may be shortened. Further, the current loops may be small.

Further, since the VCSEL 316 and semiconductor device 315 are connected by metals instead of bonding wires, the inductance may be low, and therefore the high frequency switching properties are improved. Further, since the current flowing from the semiconductor device 315 is divided evenly in the vertical two directions (+Y direction) in the figure, rather than one direction, a current path having low inductance may be ensured.

Further, since the current flows from VCSEL 316 in a direction (−Z direction, and/or, the +Y direction) perpendicular to the direction of the current path flowing into the anode of the VCSEL 316 (+X direction), a current path having low inductance may be ensured.

1. A VCSEL module comprising:
a VCSEL;
a switching element for the VCSEL disposed below the VCSEL and electrically connected to the VCSEL; and
a substrate disposed below the switching element, and electrically connected to the switching element.

2. The VCSEL module according to claim 1, further comprising a current control element disposed between the VCSEL and the switching element or between the switching element and the substrate, wherein
the current control element is electrically connected in series with the VCSEL and the switching elements.

3. The VCSEL module according to claim 2, further comprising a wiring electrode formed on the substrate, wherein
the switching element or the current control element is electrically connected to the wiring electrode via a solder ball, a stud bump or a metal piece.

4. The VCSEL module according to claim 3, wherein the connecting portion of the wiring electrode connected to a gate electrode of the current control element is formed thicker than the other portions.

5. The VCSEL module according to claim 1, further comprising a capacitor electrically connected to the VCSEL.

6. The VCSEL module according to claim 1, further comprising a first electrode made of metal, wherein
the substrate functions as a second electrode made of metal,
the VCSEL includes a VCSEL first terminal disposed on an upper surface, and a VCSEL second terminal disposed on a lower surface,
the switching element is formed in a semiconductor device,
the semiconductor device includes a first terminal connected to the first electrode and the VCSEL first terminal, a second terminal connected to the VCSEL second terminal, and a third terminal connected to the second electrode.

7. The VCSEL module according to claim 6, wherein
the semiconductor device includes a current control element for controlling a current flowing through the VCSEL, and
the current control element is connected between the second terminal and the switching element or between the switching element and the third terminal.

8. The VCSEL module according to claim 7, wherein
the semiconductor device has a rectangular planar shape including a first side, a second side and a third side perpendicular to the first side, a fourth side facing the first side, an upper surface and a lower surface,
the first terminal is disposed at an end of the upper surface along the first side close to the first electrode,
the second terminal is disposed in the central portion of the upper surface, and
the third terminal is disposed at an end of the upper surface along the second or third side.

9. The VCSEL module according to claim 8, wherein the first electrode and the first terminal are connected by a plurality of bonding wires.

10. The VCSEL module according to claim 8, wherein the second electrode and the third terminal are connected by a plurality of bonding wires.

11. The VCSEL module according to claim 8, wherein
the semiconductor device incudes a monitor circuit relating to a temperature of the VCSEL, a current flowing through the VCSEL or an amount of light emitted from the VCSEL, and
a monitor circuit terminal connected to the monitor circuit is disposed at an end along the fourth surface of the upper surface of the semiconductor device.

12. The VCSEL module according to claim 11, further comprising a third electrode connected to the monitor circuit terminal.

13. The VCSEL module according to claim 7, further comprising a resin frame formed so as to cover portions of the surfaces of the first electrode and the second electrode, and portions of the surfaces of the first terminal and the third terminal.

14. The VCSEL module according to claim 13, wherein the frame includes a support surface, and
an opening through which the VCSEL can be visually recognized is formed on the support surface.

15. The VCSEL module according to claim 14, further comprising an optical element supported by the support surface and transmitting light emitted from the VCSEL.

16. The VCSEL module according to claim 15, wherein the frame includes a convex portion disposed over the support surface and protruding inwardly from an outer wall of the frame, in order to position the optical element.

17. The VCSEL module according to claim 8, wherein, in the semiconductor device, a heat dissipation path for transferring heat radiation from the VCSEL to the second electrode is formed between the second terminal and the lower surface of the semiconductor device.

18. The VCSEL module according to claim 8, wherein
the semiconductor device incudes a fourth terminal connected to the second electrode,
the fourth terminal is disposed at the end of the upper surface along the other of the second or third side where the third terminal is disposed, and
a current flowing into the semiconductor device from the VCSEL second terminal of the VCSEL flows to the second electrode, and is divided into left and right sides of the semiconductor device via the third terminal and the fourth terminal.
